(19) United States
(12) Patent Application Publication
(10) Pub. No.: US 2026/0353722 A1
(43) Pub. Date: Nov. 5, 2026

(54) SEMICONDUCTOR STRUCTURE AND METHOD FOR MANUFACTURING SEMICONDUCTOR STRUCTURE

(71) Applicant: HUNAN SAN'AN SEMICONDUCTOR CO., LTD., Changsha (CN)

(72) Inventors: Zhigao PENG, Changsha (CN); Yonghong TAO, Changsha (CN)

(21) Appl. No.: 19/737,720

(22) Filed: Jul. 10, 2026

Related U.S. Application Data
(63) Continuation-in-part of application No. 18/241,323, filed on Sep. 1, 2023, now Pat. No. 12,707,659.

(30) Foreign Application Priority Data
Nov. 11, 2022 (CN) 202211408804.6

(51) Int. Cl. H10D 62/10; H10D 62/17

(52) U.S. Cl. CPC H10D 62/115; H10D 62/357

(57) ABSTRACT

A semiconductor structure includes a substrate, a semiconductor epitaxial layer, an active region and a terminal region, a field oxide layer, an anode layer, and a passivation layer. The anode layer is configured to extend from the active region to be arranged on a portion of the field oxide layer. The side wall and the top wall of the anode layer are connected to each other through a curved connection surface. By setting the upper corner of the side wall of the anode layer to be curved, the transition between the side wall and the top wall of the anode layer is smooth, preventing a sharp change in the inclination angle and preventing the stress concentration of the passivation layer at the corner of the side wall.

### CROSS REFERENCE TO RELATED APPLICATIONS

The present application is a continuation-in-part of US patent application No. 18/241,323, filed on Sep. 1, 2023, which claims the priority of the Chinese patent application No. 202211408804.6, filed on Nov. 11, 2022, and contents of which are incorporated herein by its entireties.

### TECHNICAL FIELD

The present disclosure relates to the field of semiconductors, and in particular to a semiconductor structure and a method of manufacturing a semiconductor structure.

### BACKGROUND

Silicon carbide serves as an important third-generation semiconductor material and has a high forbidden bandwidth, a high critical breakdown electric field and a high thermal conductivity. Therefore, a silicon carbide power element has a higher breakdown voltage, a faster switching speed and a higher operating temperature, compared to a traditional silicon-based power element. As the silicon carbide diode technology develops and is increasingly mature, an application market is increasingly extensive, including photovoltaic inverters, vehicle-mounted chargers, communication power supplies, and so on.

Different application scenarios have different reliability requirements about the elements. For example, a coastal area may have a high temperature, high salt and high humidity environment, and may have special requirements for a H3TRB of the element, which is more stringent than a traditional silicon-based AEC-Q101 standard. Currently, a power element may include a laminated structure having silicon oxide and silicon nitride or include or a silicon oxynitride passivation layer to protect the power element against moisture. In the art, the passivation layer or a material layer may be cracked easily, resulting in failure of the element.

### SUMMARY OF THE DISCLOSURE

The present disclosure aims to, for example, provide a semiconductor structure and a method of manufacturing a semiconductor structure, reducing the failure of the element caused by the passivation layer being cracked in the art.

The present disclosure is achieved as follows.

In a first aspect, a semiconductor structure is provided and includes: a substrate; a semiconductor epitaxial layer, disposed on the substrate; a field oxide layer, arranged on the semiconductor epitaxial layer; an anode layer, configured to extend from the semiconductor epitaxial layer to be arranged on a portion of the field oxide layer, wherein the anode layer comprises: a top wall, facing away from the semiconductor epitaxial layer; a side wall, connected to the field oxide layer; and a connection surface, connected between the side wall of the anode layer and the top wall of the anode layer; and the side wall is curved and outwardly convex toward a direction facing away from the substrate; and a passivation layer, configured to cover the field oxide layer and extend along the side wall and to cover at least the connection surface.

In a second aspect, a method of manufacturing a semiconductor structure is provided and includes: providing a substrate structure, wherein the substrate structure comprises: a substrate; a semiconductor epitaxial layer, disposed on the substrate; and a field oxide layer, arranged on the semiconductor epitaxial layer; forming an anode layer, wherein the anode layer is configured to extend from the semiconductor epitaxial layer to cover a portion of the field oxide layer; the anode layer comprises: a top wall, facing away from the semiconductor epitaxial layer; a side wall, connected to the field oxide layer; and a connection surface, connecting between the side wall and the top wall of the anode layer; and the side wall is curved and outwardly convex toward a direction facing away from the substrate; and forming a passivation layer on the field oxide layer and the anode layer, wherein the passivation layer is configured to cover the field oxide layer and extends along the side wall to cover at least the connection surface.

### BRIEF DESCRIPTION OF THE DRAWINGS

In order to illustrate the technical solutions of embodiments of the present disclosure more clearly, the accompanying drawings used for describing the embodiments will be briefly described in the following. It should be understood that the following accompanying drawings illustrate only some embodiments of the present disclosure and shall not be interpreted as limiting the scope of the present disclosure. Any ordinary skilled person in the art may obtain other relevant accompanying drawings based on these drawings without creative work.

FIG. 1 is a schematic view of a semiconductor structure according to an embodiment of the present disclosure.

FIG. 2 is a schematic view of a semiconductor structure according to an embodiment of the present disclosure.

FIG. 3 is a schematic view of a semiconductor structure according to another embodiment of the present disclosure.

FIG. 4 is a schematic view of a SBD type semiconductor structure according to some embodiments of the present disclosure.

FIG. 5 is a schematic view of a SBD type semiconductor structure according to another some embodiments of the present disclosure.

FIG. 6 is a schematic cross-sectional view of a semiconductor structure according to an embodiment of the present disclosure, illustrating an arcuate side wall of the anode layer, where an absolute value of a tangent slope of the side wall continuously decreases from a lower end thereof toward an upper end thereof.

FIG. 7 is a detail view of a region of the side wall of the anode layer shown in FIG. 6, illustrating a radius of curvature of the arcuate profile that gradually increases from a lower end of the side wall toward an upper end thereof.

FIG. 8 is an enlarged view showing a portion of the anode layer, illustrating that the side wall and the connection surface form an integral arcuate contour without any inflection point or sharp corner therebetween.

FIG. 9 is an enlarged view showing a portion of the anode layer, illustrating that the side wall, the connection surface, and at least a portion of the top wall jointly form a continuous arcuate contour without any abrupt change in slope or sharp corner therebetween.

FIG. 10 is an enlarged view showing a portion of the anode layer, illustrating that an angle between a tangent to a connection surface of the anode layer and a surface of the field oxide layer continuously decreases from a lower end of the connection surface toward an upper end thereof.

FIG. 11 is a flow chart of a method of manufacturing a semiconductor structure according to an embodiment of the present disclosure.

FIG. 12 is another flow chart of a method of manufacturing a semiconductor structure according to an embodiment of the present disclosure.

FIG. 13 is another flow chart of a method of manufacturing a semiconductor structure according to an embodiment of the present disclosure.

FIG. 14 is another flow chart of a method of manufacturing a semiconductor structure according to an embodiment of the present disclosure.

FIG. 15 is another flow chart of a method of manufacturing a semiconductor structure according to an embodiment of the present disclosure.

FIG. 16 is another flow chart of a method of manufacturing a semiconductor structure according to an embodiment of the present disclosure.

FIG. 17 is another flow chart of a method of manufacturing a semiconductor structure according to an embodiment of the present disclosure.

FIG. 18 is another flow chart of a method of manufacturing a semiconductor structure according to an embodiment of the present disclosure.

Reference numerals: 100 semiconductor structure; 110 substrate; 120 semiconductor epitaxial layer; 121 active region; 123 terminal region; 130 field oxide layer; 131 first window; 140 anode layer; 141 protrusion portion; 141a recessed portion; 142 top wall; 143side wall; 144 connection surface; 145 metal layer; 146 connection portion; 147 photoresist layer; 150 passivation layer; 160 protective layer; 161 second window; P1 a point at a lower end of the side wall; P2 a point at an upper end of the side wall; L1 tangent line at P1; L2 tangent line at P2; HL horizontal reference line; α1 first angle between L1 and HL; α2 second angle between L2 and HL; R1 radius of curvature at the lower end of the side wall; R2 radius of curvature at the upper end of the side wall; P3 a point at a lower end of the connection surface; P4 a point at an upper end of the connection surface; L3 tangent line at P3; L4 tangent line at P4; α3 third angle between L3 and HL; α4 fourth angle between L4 and HL.

### DETAILED DESCRIPTION

In order to make the purpose, technical solutions and advantages of embodiments of the present disclosure clearer, the technical solutions in the embodiments of the present disclosure will be described clearly and completely by referring to the accompanying drawings in the embodiments of the present disclosure. Obviously, the described embodiments are a part of but not all of the embodiments of the present disclosure. Any assembly described and illustrated in the accompanying drawings of the embodiments of the present disclosure can be arranged and designed in various configurations.

Therefore, the following detailed description of the embodiments of the present disclosure provided in the accompanying drawings is not intended to limit the scope of the claims of the present disclosure, but merely indicates selected embodiments of the present disclosure. Based on the embodiments in the present disclosure, all other embodiments obtained without creative work by any ordinary skilled person in the art shall fall within the scope of the present disclosure.

It should be noted that similar reference numerals and letters indicate similar items in the accompanying drawings below. Therefore, once an item has been defined in one accompanying drawing, the item does not need to be further defined and explained in subsequent drawings.

In the description of the present disclosure, to be noted that, the terms “upper”, “lower”, “inner”, “outer”, and so on, are used to indicate an orientation or positional relationship based on the orientation or positional relationship shown in the accompanying drawings or indicate the orientation or positional relationship in which the product of the present disclosure is customarily placed for use. The terms are used to facilitate and simplify the description of the present disclosure and do not indicate or imply that the described devices or elements must have a particular orientation or must be constructed and operated in a particular orientation. Therefore, the terms shall not be interpreted as limiting the present disclosure.

Furthermore, the terms “first”, “second”, and so on, are used only to distinguish the description and shall not be understood as indicating or implying relative importance.

The present disclosure provides a novel semiconductor structure and a method of manufacturing the semiconductor structure. To be noted that features in the embodiments of the present disclosure can be combined with each other without conflict.

Currently, a power element may include a laminated structure having silicon oxide and silicon nitride or include or a silicon oxynitride passivation layer to protect the power element against moisture. However, in practice, the power element may be subjected to high and low temperature cycles. In the art, etching is only performed in a direction perpendicular to a surface of a silicon wafer, and a structure formed by the etching is usually a vertical chipping surface. Therefore, for a passivation layer or a material layer, a stress may be concentrated at a corner of the etched metal, leading to cracks of the passivation layer or the material layer. Moisture may enter through the cracks at an accelerated rate under an effect of a high electric field, leading to failure of the power element.

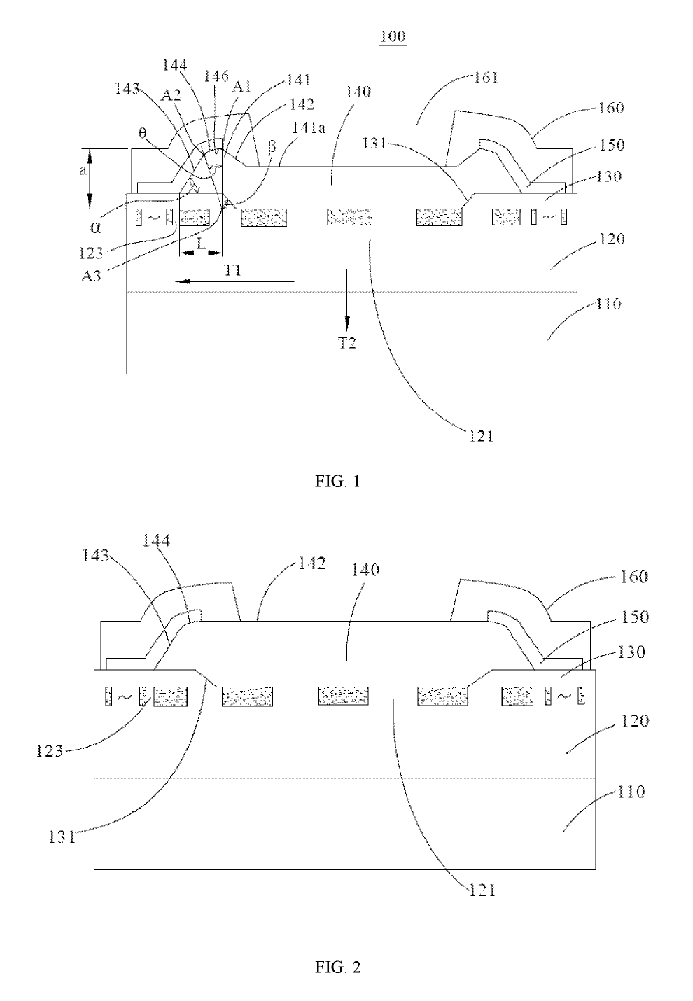

As shown in FIGS. 1 or 2, the present embodiment provides a semiconductor structure 100. In the present embodiment, conditions for lithography and etching may be optimized, for example, conditions for lithography and dry etching are optimized, such that a corner of the anode layer 140 may be flatter, reducing the problem of cracks caused by stress concentration at the corner due to the anode layer 140 being steep and straight. Therefore, moisture resistance of the semiconductor structure may be improved.

The present embodiment provides a semiconductor structure 100, including a substrate 110, a semiconductor epitaxial layer 120, a field oxide layer 130, an anode layer 140, and a passivation layer 150. The semiconductor epitaxial layer 120 is arranged on the substrate 110 and is arranged with an active region 121 and a terminal region 123. The active region 121 and the terminal region 123 are extending from an inside the semiconductor epitaxial layer 120 facing away from a surface (top surface) of the substrate 110. The field oxide layer 130 is arranged on the semiconductor epitaxial layer 120. The field oxide layer 130 is configured to be arranged on the semiconductor epitaxial layer 120, for example, is configured to extend from an edge of the active region 121 towards the terminal region 123. The anode layer 140 is configured to extend from the semiconductor epitaxial layer 120 to be arranged on a part of the field oxide layer 130, for example, is configured to extend from the active region 121 to be arranged on a part of the field oxide layer 130. That is, the anode layer 140 is arranged on the field oxide layer 130 and covers a part of the field oxide layer 130. The anode layer 140 includes: a top wall 142 facing away from the semiconductor epitaxial layer 120 (specifically, the active region 121) and a side wall 143 facing towards and connected to the field oxide layer 130. The side wall 143 of the anode layer 140 is connected to the top wall 142 of the anode layer 140 by a connection surface 144. The connection surface 144 is curved and outwardly convex toward the direction facing away from the substrate 110 to enable the side wall to be smoothly transitioned to the top wall of the anode layer 140. The passivation layer 150 is configured to cover a part of the field oxide layer 130 and extends to cover the connection surface 144. In more detail, the transition portion, which is extending from the side wall to the top wall, does not have any sharp corner, i.e., the corner has no sharp tip. For example, the transition portion may be a round corner. It is understood that, the present disclosure does not require a specific shape of the transition portion, as long as no sharp corner or sharp tip is formed.

To be noted that, the power element is often subject to high and low temperature cycles in practice, and a thermal expansion coefficient of the passivation layer, a thermal expansion coefficient of the anode layer, and a thermal expansion coefficient of the protective layer are different from each other. Therefore, the passivation layer may be cracked when an excessive shear force is applied. Especially, the stress may be concentrated at a portion of the passivation layer located at the corner of the anode layer, and therefore, the corner of the anode layer may be cracked. In addition, the moisture may enter an inside of the power element through the cracks in an accelerated rate under an action of the high electric field, leading to the failure of the power element.

In the present embodiment, by arranging a curved connection surface 144 between the side wall and the top wall 142 of the anode layer 140, the transition between the side wall 143 and the top wall 142 of the anode layer 140 may be smooth. In this way, a sharp change in an angle between the side wall 143 and the top wall 142 of the anode layer 140 may be reduced, such that the stress concentration at a part of the passivation layer above the corner may be reduced, and the moisture entering the power element, which may cause the failure, may be reduced.

Furthermore, since the passivation layer is configured to cover the field oxide layer 130 and to extend to cover the connection surface 144, coverage of the passivation layer 150 over the anode layer 140 may be standardized, and cracks caused by thermal expansion may be reduced, further enhancing the moisture resistance of the power element.

In addition, compared to the related art where a power element may include a laminated structure having silicon oxide and/or silicon nitride or include or a silicon oxynitride passivation layer to protect the power element against moisture, in the present disclosure, only the corner structure of the anode layer is modified, and a buffering material layer may not be arranged. Therefore, in the present disclosure, the stress concentration of the passivation layer may be reduced, while an interlayer structure of the power element may be reduced, such that a package height of the power element may be reduced. Therefore, the power element may be miniaturized.

Furthermore, since the transition between the side wall 143 and the top wall 142 is smooth, the passivation layer 150 may be enabled to extend upwards when being deposited, such that a climbing problem of the passivation layer 150 above the anode layer 140 may be solved, the passivation layer 150 may be formed better, improving the reliability of the power element.

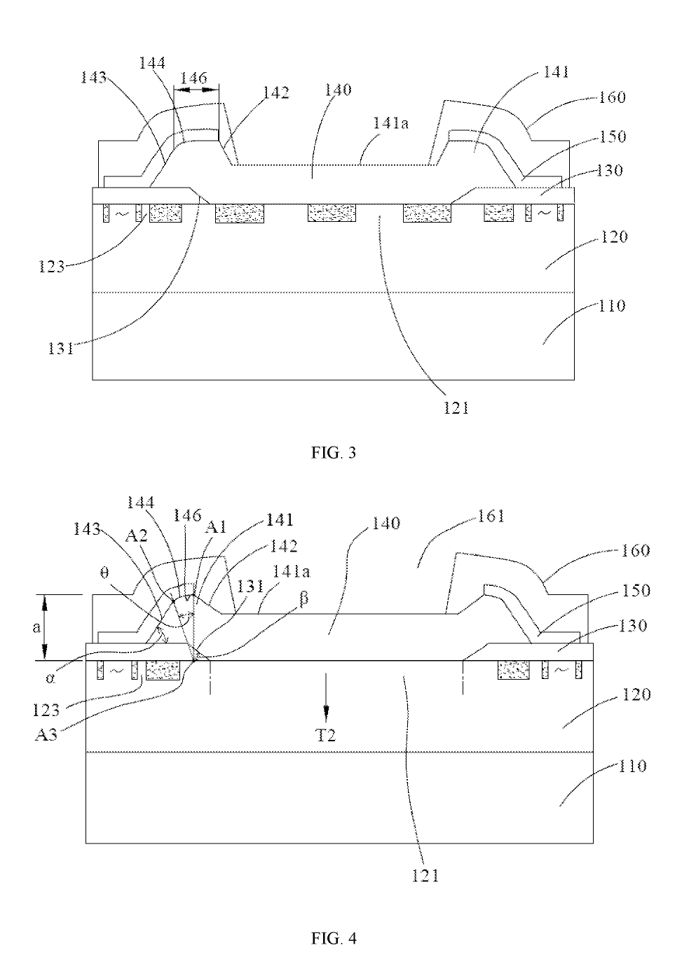

In some embodiments, as shown in FIG. 3, the top wall 142 of the anode layer 140 is arranged with a recessed portion 141a. An edge of the recessed portion 141a is connected to the side wall 143 of the anode layer by a connection portion 146. A section of the connection portion 146 is the connection surface 144.

Furthermore, the field oxide layer 130 is arranged on the semiconductor epitaxial layer 120 and defines a first window 131 exposing the active region 121.

Exemplarily, a protrusion portion 141 is formed on a position of the anode layer 140 corresponding to an edge of the first window 131. The recessed portion 141a is formed between two protrusion portions 141 on both sides. The side wall 143 of the anode layer 140 extends from the protrusion portion 141 to the field oxide layer 130. A connection between a surface of the protrusion portion 141 and the side wall 143 of the anode layer 140 is the connection portion 146. The passivation layer 150 covers the side wall 143 and extends to cover the protrusion portion 141.

In some embodiments, as shown in FIGS. 1 or 4, the edge of the recessed portion 141a is connected to the side wall 143 of the anode layer 140 through the connection portion 146. The connection portion 146 is a connection surface 144 being curved.

Furthermore, in some embodiments, a section of the connection portion 146 is the connection surface 144, and the other section of the connection portion 146 is a part of the top wall 142 of the anode layer 140. That is, the top wall 142 of the anode layer 140 includes: the recessed portion 141a and the remaining section of the connection portion 146 other than the connection surface.

In some embodiments, as shown in FIGS. 1, 3, or 4, the passivation layer 150 covers the side wall 143 of the anode layer 140 and extends to cover the connection portion 146.

In some embodiments, as shown in FIGS. 1 or 3, a length of the part of the passivation layer 150 covering the connection portion is between 2 μm and 100 μm. That is, a connection width of the passivation layer 150 covering the connection portion 146 of the anode layer 140 (i.e., the above-mentioned “length” described above) is in a range from 2 μm to 100 μm. The connection width of the passivation layer 150 covering the connection portion 146 of the anode layer 140 refers to a width of a surface of the connection portion between the passivation layer 150 and the anode layer 140. That is, a width of a part of the surface of the anode layer 140 where the passivation layer 150 is deposited. Further, the connection width is defined based on the width of the surface of the connection. The connection width may also be understood as a length a part of the passivation layer 150 extending from a connection (that is, the connection between the curved connection surface 144 and the sloped and straight side wall 143, as shown in the cross-sectional view) between the connection surface 144 and the side wall 143 to a connection (that is, the connection surface 144) between the connection portion and the top wall 142 that is sloped and straight.

Exemplarily, the connection width of the part of the passivation layer 150 covering the connection portion 146 of the anode layer 140 is 50 μm.

In the above example, the passivation layer 150 covers the connection portion 146 that extends to reach the anode layer 140 and has a certain connection width. In this way, the coverage of the passivation layer 150 may not be excessively wide, such that an excessively large shear force due to inconsistent thermal expansion coefficients of dissimilar materials may be reduced, and therefore, the problem of cracks in the passivation layer 150 caused by the excessively large shear force may be reduced.

To be noted that, in the present embodiment, the protrusion portion 141 is disposed at an edged region of the top wall 142 of the anode layer 140, and the top wall 142 and the side wall 143 of the anode layer 140 are connected with each other through the connection portion 146, the connection portion 146 is curved in overall. That is, as shown in FIG. 1, the connection surface 144 is curved and directly connected to the top wall 142 and the side wall 143. In some embodiments, as shown in FIG. 3, the connection portion 146 may alternatively include a connection surface 144 and a transition surface. The connection surface 144 is curved, and the transition surface is flat. That is, the passivation layer 150 may be transitioned through the curved connection surface and is further smoothed out slightly through the transition surface. In this case, the transition surface is the remaining part of the connection portion 146 other than the connection surface 144, or in other words, the transition surface is a portion of the top wall 142 of the anode layer 140.

In some embodiments, the connection surface 144 of the anode layer 140 is curved and outwardly convex toward a direction facing away from the substrate 110. As used herein, “outwardly convex” with respect to the connection surface 144 means that the arcuate profile of the connection surface 144 bulges outward (away from the substrate 110 and away from the active region 121), forming a smooth, convex transitional surface between the side wall 143 and the top wall 142. Such outwardly convex configuration of the connection surface 144 cooperates with the outwardly convex configuration of the side wall 143 to provide a continuously smooth and gradually changing path for the passivation layer 150 to climb from the field oxide layer 130 to the side wall 143, then to the connection surface 144, and finally to the top wall 142, without any abrupt change in slope or sharp corner. This further reduces stress concentration in the passivation layer 150 at the junction between the side wall 143 and the connection surface 144, and at the junction between the connection surface 144 and the top wall 142, thereby preventing cracks and improving the reliability of the semiconductor structure 100.

In some embodiments, the side wall 143 of the anode layer 140 is curved and outwardly convex toward a direction facing away from the substrate 110. As used herein, “outwardly convex” means that the arcuate profile of the side wall 143 bulges outward (away from the substrate 110 and away from the active region 121), rather than being straight or concave. Such outwardly convex configuration allows the passivation layer 150 to climb along the side wall 143 with a gradually changing slope, reducing stress concentration at a junction between the side wall 143 and the field oxide layer 130 and at a junction between the side wall 143 and the connection surface 144. Compared to a side wall having a concave profile or a straight inclined wall, the outwardly convex side wall 143 provides a smoother transition for the passivation layer 150 from the field oxide layer 130 toward the connection surface 144 and the top wall 142, thereby preventing cracks in the passivation layer 150 and improving the moisture resistance and reliability of the semiconductor structure 100.

In some embodiments, as shown in FIG. 6, the side wall 143 of the anode layer 140 has a tangent slope, and an absolute value of the tangent slope continuously decreases in a direction from a lower end of the side wall 143 adjacent to the field oxide layer 130 toward an upper end of the side wall 143 adjacent to the connection surface 144. As used herein, the “lower end of the side wall” refers to an end portion of the side wall 143 adjacent to the field oxide layer 130 (i.e., the end of the side wall 143 closest to the field oxide layer 130). The “upper end of the side wall” refers to an end portion of the side wall 143 adjacent to the connection surface 144 (i.e., the end of the side wall 143 closest to the connection surface 144). As shown in FIG. 6, a tangent line L1 at a point P1 at the lower end of the side wall 143 forms a first angle α1 with a horizontal reference line HL, and a tangent line L2 at a point P2 at the upper end of the side wall 143 forms a second angle α2 with the horizontal reference line HL, where α1 is greater than α2. The horizontal reference line HL is parallel to a surface of the field oxide layer 130. In other words, an absolute value of the tangent slope of the side wall 143 is larger at the lower end of the side wall 143 (i.e., the side wall 143 is steeper adjacent to the field oxide layer 130) and smaller at the upper end of the side wall 143 (i.e., the side wall 143 is gentler adjacent to the connection surface 144). Such configuration allows the passivation layer 150 to climb smoothly along the side wall 143 from the field oxide layer 130 toward the connection surface 144, with reduced stress concentration and improved resistance to cracking. That is to say, an angle between a tangent to the side wall 143 and a surface of the field oxide layer 130 continuously decreases in the direction from the lower end of the side wall 143 toward the upper end of the side wall 143. As shown in FIG. 6, the angle α₁ at the lower end (between tangent line L1 and the horizontal reference line HL, which is parallel to the surface of the field oxide layer 130) is greater than the angle α₂ at the upper end (between tangent line L2 and HL). This progressive decrease in angle from the lower end to the upper end of the side wall 143 corresponds to the continuous decrease in the absolute value of the tangent slope of the side wall 143, which reduces stress concentration in the passivation layer 150 during deposition and climbing.

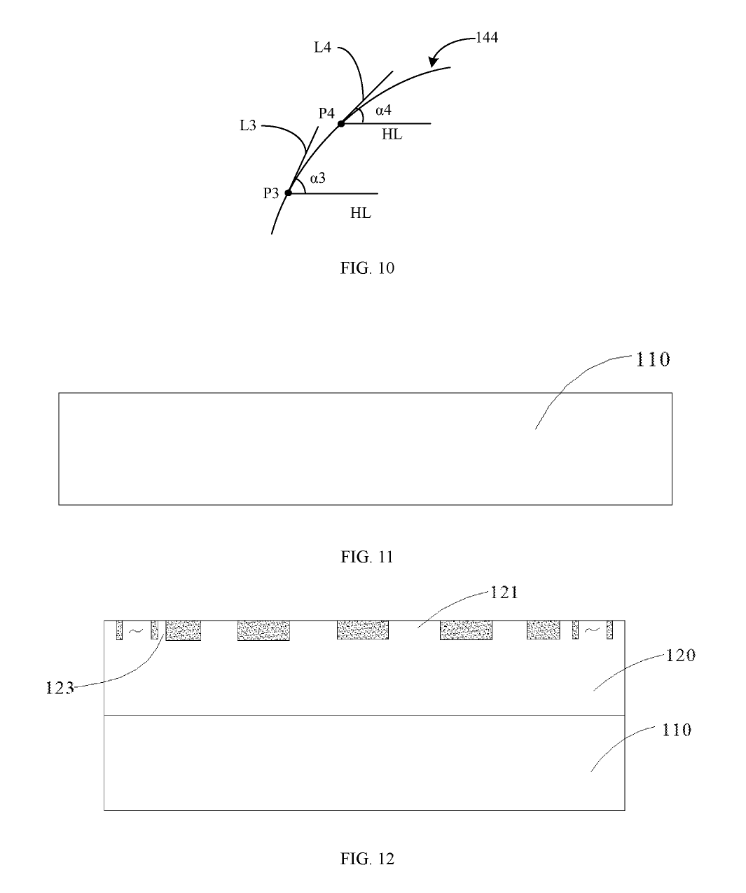

In some embodiments, as shown in FIG. 10, an angle between a tangent to the connection surface 144 and a surface of the field oxide layer 130 continuously decreases in a direction from a lower end of the connection surface 144 toward an upper end of the connection surface 144. As used herein, the “lower end of the connection surface” refers to an end portion of the connection surface 144 adjacent to the side wall 143 (i.e., the end of the connection surface 144 closest to the side wall 143). The “upper end of the connection surface” refers to an end portion of the connection surface 144 adjacent to the top wall 142 (i.e., the end of the connection surface 144 closest to the top wall 142). As shown in FIG. 10, a tangent line L3 at a point P3 at the lower end of the connection surface 144 forms a third angle α3 with a horizontal reference line HL (which is parallel to the surface of the field oxide layer 130), and a tangent line L4 at a point P4 at the upper end of the connection surface 144 forms a fourth angle α4 with the horizontal reference line HL, where α3 is greater than α4. In other words, the angle between the tangent to the connection surface 144 and the surface of the field oxide layer 130 is larger at the lower end of the connection surface 144 adjacent to the side wall 143, and smaller at the upper end of the connection surface 144 adjacent to the top wall 142. Such configuration allows the connection surface 144 to serve as a progressively gentler transitional surface from the side wall 143 toward the top wall 142, thereby enabling the passivation layer 150 to climb smoothly across the connection surface 144 with gradually reduced stress concentration, and effectively preventing cracks at the junction between the side wall 143 and the connection surface 144, as well as at the junction between the connection surface 144 and the top wall 142. This, in combination with the gradually decreasing angle of the side wall 143, provides a continuously smooth climbing path for the passivation layer 150 from the field oxide layer 130 to the top wall 142, further improving the overall reliability and moisture resistance of the semiconductor structure 100.

In some embodiments, the angle between a tangent to the side wall 143 and a surface of the field oxide layer 130 continuously decreases from the lower end of the side wall 143 toward the upper end thereof. This angle is referred to as a second angle α. In some embodiments, the second angle α is an acute angle. That is, the tangent to the side wall 143 at any point thereof forms an acute angle with the surface of the field oxide layer 130, and the acute angle progressively decreases from the lower end toward the upper end of the side wall 143. Such configuration ensures that the passivation layer 150 experiences a gradually changing slope during deposition and climbing, thereby reducing stress concentration and preventing cracks.

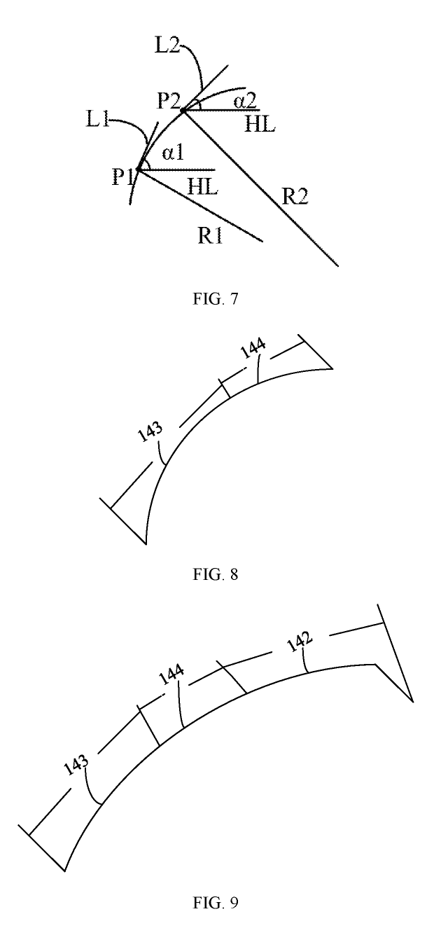

In some embodiments, as shown in FIG. 7, in a cross-sectional view, the side wall 143 of the anode layer 140 has an arcuate profile. A radius of curvature of the arcuate profile gradually increases in a direction from a lower end of the side wall 143 toward an upper end of the side wall 143. For example, as shown in FIG. 7, the radius of curvature at point P1 at the lower end of the side wall is R1, and the radius of curvature at point P2 at the upper end of the side wall is R2, wherein R2 > R1. That is, the side wall 143 is more curved (having a smaller radius of curvature R1) at the lower end thereof adjacent to the field oxide layer 130, and becomes less curved (having a larger radius of curvature R2) at the upper end thereof adjacent to the connection surface 144, approaching a substantially non-curved profile at the upper end portion thereof. Such configuration further facilitates the climbing of the passivation layer 150 along the side wall 143 and reduces stress concentration.

In some embodiments, as shown in FIG. 8, the side wall 143 and the connection surface 144 of the anode layer 140 form an integral arcuate contour. That is, the side wall 143 itself is curved rather than being a straight inclined wall, and the curved side wall 143 merges seamlessly into the curved connection surface 144. The integral arcuate contour has no inflection point or sharp corner between the side wall 143 and the connection surface 144. The passivation layer 150 extending along such integral arcuate contour experiences reduced stress concentration at a junction between the side wall 143 and the connection surface 144.

In some embodiments, as shown in FIG. 9, the side wall 143, the connection surface 144, and at least a portion of the top wall 142 jointly form a continuous arcuate contour. For example, in the embodiment shown in FIG. 3 where the top wall 142 has a recessed portion 141a and a connection portion 146 connecting the recessed portion 141a to the side wall 143, the connection portion 146 comprises the connection surface 144 and a portion of the top wall 142. In such embodiment, the portion of the top wall 142, the connection surface 144, and the side wall 143 are arranged to form a continuous arcuate contour extending from the top wall 142 through the connection surface 144 to the side wall 143. The continuous arcuate contour has no abrupt change in slope or sharp corner between the top wall 142, the connection surface 144, and the side wall 143, thereby allowing the passivation layer 150 to climb smoothly and uniformly along the entire arcuate contour.

The top wall 142 of the anode layer 140 has the recessed portion 141a, such that the anode layer 140 has an upper corner and a lower corner. Further, since a section of the connection portion 146 between the edge of the recessed portion 141a and the side wall 143 of the anode layer is the curved connection surface 144, the upper corner and the lower corner of the anode layer 140 are transitioned smoothly. That is, the side wall 143 of the anode layer 140 is smoothly transitioned to the top wall. In this way, cracks may not be easily generated at the smooth corners of the passivation layer 150, the moisture resistance of the power element may be improved. In addition, the smooth corners also facilitate the climbing of the passivation layer 150, improving the forming quality of the passivation layer 150.

In addition, the passivation layer 150 extends to cover a top of the protrusion portion 141 and corresponds to the edged region of the first window 131. Specifically, the passivation layer 150 extends from the field oxide layer 130 towards the side wall 143 of the anode layer 140 and continues to climb upwards to reach the top of the protrusion portion 141, such that a good passivation effect may be achieved, and external electrical connection of the anode layer 140 may not be affected. In addition, the passivation layer 150 completely covers the upper corner and the lower corner of the side wall 143 of the anode layer 140. The passivation layer 150 may be a double medium layer of silicon oxide and silicon nitride or may be a silicon oxynitride medium. A thickness of the passivation layer 150 is in a range of 8000 A to 15000 A. Of course, the material and the thickness of the passivation layer 150 is only exemplarily here and is not limited by the present disclosure.

In some embodiments, as shown in FIG. 2, the top wall 142 of the anode layer 140 may be flat (i.e., the recessed portion 141a is not included). Specifically, a portion of the anode layer 140 disposed above the active region 121 is flat.

In some embodiments, as shown in FIGS. 1 or 2, the side wall 143 of the anode layer 140 is inclined. An end of the side wall 143 of the anode layer 140 is inclined towards the active region 121, and the other end extends to reach the field oxide layer 130. In detail, the inclined side wall 143 may be understood as: an end of the side wall 143 is arranged on the field oxide layer 130, and the side wall 143 extends facing away from the active region and is inclined relative to a plane on which a top surface of the active region is arranged. In detail, an angle between the side wall of the anode layer and the surface of the field oxide layer is a second angle α, and the second angle α is a sharp angle.

In some embodiments, an angle between a tangent to the side wall 143 of the anode layer 140 and a surface of the field oxide layer 130 may be less than an angle that is typically required by the advanced integrated circuit applications in the art. For example, the advanced integrated circuit application typically requires a side wall being 88° to 89° vertical. Therefore, in the present embodiment, the angle between the side wall 143 of the anode layer 130 and the surface of the field oxide layer 130 is in a range of 0° to 88°.

In the present embodiment, since the side wall 143 of the anode layer 140 is non-vertical and inclined towards the field oxygen layer 130, the side wall 143 may be smoothly transitioned to the top wall 142 anode layer 140. In this way, a sharp change in the angle (the angle between the side wall 143 and the top wall 142 being excessively large) between the side wall 143 and the top wall 142 of the anode layer 140 may be reduced, the stress concentration at the position of the passivation layer above the transitioned portion may be reduced, and the entry of moisture into the power element, which may result in the failure of the power element, may be reduced.

In some embodiments, an end of the arc (viewed from the cross-sectional view) of the connection surface 144 near the top wall 142 is projected towards the semiconductor epitaxial layer 120, generating a first projection. A side of the field oxide layer 130 facing away from the semiconductor epitaxial layer 120 has a second projection. The first projection intersects the second projection (a position of the first projection corresponds to a position of the second projection). That is, a projection of an intersection between the arc of the connection surface 144 and the top wall 142 in a direction extending from the semiconductor epitaxial layer 120 towards the substrate 110 falls on the side of the field oxide layer 130 facing away from the semiconductor epitaxial layer 120.

In some embodiments, the connection surface 144 includes a first point connected to the top wall 142 and a second point connected to the side wall 143. In the direction extending from the semiconductor epitaxial layer 120 towards the substrate 110, a projection point of the first point projected onto the surface of the semiconductor epitaxial layer 120 facing away from the substrate 110 is a third point. An angle between a line connecting the third point with the second point and a line connecting the third point with the first point is a first angle θ, which is greater than 5°.

It shall be understood that, when the first angle θ is excessively small, such as less than 5°, the stress concentration of the passivation layer 150 at the corner of the side wall 143 is still significant. Therefore, in order to better solve the stress concentration of the passivation layer 150 at the corner of the side wall 143 and to reduce the cracks at the corner on the side wall 143 caused by the stress concentration of the passivation layer 150, the first angle θ is set to be as greater than 5°. In this way, the arc of the connection surface being excessively short, which may be caused by the first angle θ being excessively small, may be solved, such that the stress concentration of the passivation layer corresponding to the corner of the side wall 143 may be reduced better. In this way, the arc of the connection surface being excessively short, which may be caused by the first angle θ being excessively small, may be solved, cracks in the passivation layer at the corner of the side wall may be reduced. Therefore, the moisture resistance of the power element may be improved, and the stability of the power element may be improved.

In some embodiments, the connection surface 144 includes the first point connected to the top wall 142 and the second point connected to the side wall 143. In the direction extending from the semiconductor epitaxial layer 120 towards the substrate 110, a projection point of the first point projected onto the surface of the field oxide layer 130 is the third point. The angle between the line connecting the third point with the second point and the line connecting the third point with the first point is the first angle θ, which is less than 45°.

It may be understood that, when the first angle θ is excessively large, such as greater than or equal to 45°, the lower corner of the side wall 143 turning along the arc of the connection surface 144 may be steeper and straighter. In this way, a portion of the passivation layer 150 at the connection between the side wall 143 and the field oxide layer 130 may be steep and straight, such that the passivation layer 150 may be cracked easily at the position where the side wall 143 is connected with the field oxide layer 130. Therefore, in order to reduce the steepness of the passivation layer 150 at the lower corner of the side wall 143, the first angle θ is set to be as less than 45°. Therefore, the side wall 143 that turns down from arc of the connection surface 144 has a gentle slope. In this way, less stress is concentrated at the passivation layer 150 corresponding to the lower corner of the side wall 143 of the anode layer 140, and cracks may not be generated at the passivation layer 150 corresponding to the lower corner of the side wall 143 of the anode layer 140.

Further, since the first angle θ is defined to be less than 45°, the side wall 143 that turns down from the arc of the connection surface 144 may have a gentler slope (a tangent extending from the arc towards the slope downwards). In this way, the passivation layer 150 may grow by climbing along the gentle slope, facilitating the passivation layer to grow uniformly.

In order to reduce the stress concentration at the passivation layer 150 corresponding to the upper corner and the lower corner of the side wall 143 and to reduce the cracks caused by the stress concentration at the corners due to the steep and straight anode layer 140 to improve the moisture resistance of the power element, in the present embodiments, the connection surface 144 includes the first point connected to the top wall 142 and the second point connected to the side wall 143. In the direction extending from the semiconductor epitaxial layer 120 towards the substrate 110, a projection point of the first point projected onto the surface of the field oxide layer 130 is the third point. An angle between the line connecting the third point with the second point and the line connecting the third point with the first point is a first angle θ, which is greater than 5° and less than 45°.

Additionally, by providing the side wall 143 with a tangent slope that continuously decreases from the lower end to the upper end thereof (as shown in FIG. 6), or an arcuate profile with a radius of curvature that gradually increases from the lower end to the upper end thereof (as shown in FIG. 7), the passivation layer 150 can climb along the side wall 143 with significantly reduced stress concentration. Compared to a side wall having a constant slope (i.e., a straight inclined wall), the continuously decreasing tangent slope configuration allows the passivation layer 150 to transition more smoothly from the side wall 143 to the connection surface 144 and the top wall 142, thereby reducing shear stress caused by differential thermal expansion between the passivation layer 150 and underlying layers, and effectively preventing cracks in the passivation layer 150.

Additionally, by configuring the connection surface 144 to be curved and outwardly convex toward the direction facing away from the substrate 110, the passivation layer 150 can transition smoothly from the side wall 143 to the top wall 142 without any abrupt change in slope or sharp corner. This outwardly convex configuration of the connection surface 144 ensures that the passivation layer 150 experiences a progressively varying slope as it climbs from the side wall 143 to the top wall 142, thereby reducing stress concentration and preventing cracks at the corner between the connection surface 144 and the top wall 142. The combination of the outwardly convex side wall 143 and the outwardly convex connection surface 144 provides a continuously smooth climbing path for the passivation layer 150 from the field oxide layer 130 to the top wall 142, further improving the moisture resistance and reliability of the semiconductor structure 100.

Since the first angle θ is greater than 5° and less than 45°, the stress concentration of the passivation layer 150 corresponding to both the upper corner and the lower corner of the side wall 143 of the anode layer 140 may be reduced. In this way, cracks of the passivation layer 150 at the upper corner and the lower corner of the side wall 143 of the anode layer 140 due to the stress concentration may be reduced.

In some embodiments, the first angle θ is in a range from 15° to 30°, such that the stress concentration at the passivation layer 150 corresponding to the upper corner and the lower corner of the side wall 143 may be reduced better, the cracks caused by the stress concentration at the corners due to the anode layer 140 being steep and straight may be reduced, and the moisture resistance of the power element may be improved.

In some embodiments, in a direction T2 from the semiconductor epitaxial layer 120 to the substrate 110, a side of the arc of the connection surface 144 near the top wall 142 has a distance a facing away from a side of field oxide layer 130 near the semiconductor epitaxial layer 120. To be noted that, ideally, the arc of the connection surface 144 is or close to a part of a right circle, a length L of the arc of the connection surface 144 may be set to be a*2πθ/360. Of course, in other cases where the arc of the connection surface 144 is not a part of the right circle, the length L of the arc may be calculated by other means, which will not be limited herein.

To be noted that, the distance a is a distance from a first point A1 at which the connection surface 144 is connected with the top wall 142 to a third point A3, which is a projection point of the first point A1 projected onto the semiconductor epitaxial layer 120.

In some embodiments, as shown in FIGS. 1 or 2, the field oxide layer 130 includes a top surface facing away from the semiconductor epitaxial layer 120, a bottom surface opposite to the top surface and adjacent to the semiconductor epitaxial layer 120, and a side surface connecting with the top surface and the bottom surface. The top surface of the field oxide layer 130 is opposite to the terminal region 123 and is substantially parallel to a surface of the terminal region 123 (i.e., substantially parallel to the top surface of the semiconductor epitaxial layer 120). The side surface of the field oxide layer 130 includes a first side connected to the top surface and a second side connected to the bottom surface. The first side is adjacent to the terminal region 123. In this way, the side surface of the field oxide layer 130 is inclined towards the terminal region 123 in a direction extending from the second side towards the first side.

In some embodiments, the line connecting the first point A1 with the third point A3 may intersect the top surface of the field oxide layer 130. That is, the connection surface 144 of the anode layer entirely lies within the top surface of the field oxide layer 130, such that the stress at the corners of the anode layer 140 may be reduced. Exemplarily, when the anode layer 140 has a uniform thickness, and when the top surface of the field oxide layer 130 is parallel to the surface of the semiconductor epitaxial layer 120, in the direction from the semiconductor epitaxial layer 120 to the substrate 110, a sum of the thickness of the anode layer 140 and the thickness of the field oxide layer 130 may be a, as shown in FIG. 1.

In some embodiments, since the side surface of the field oxide layer 130 is inclined towards the terminal region 123 of the semiconductor epitaxial layer 120, the line connecting the first point A1 with the third point A3 intersects the side surface of the field oxide layer 130. That is, the connection surface 144 of the anode layer 140 is projected onto the semiconductor epitaxial layer 120, generating a first projection; the side surface of the field oxide layer 130 is projected onto the semiconductor epitaxial layer 120, generating a second projection; and the first projection at least partially locates within the second projection, as shown in FIG. 4.

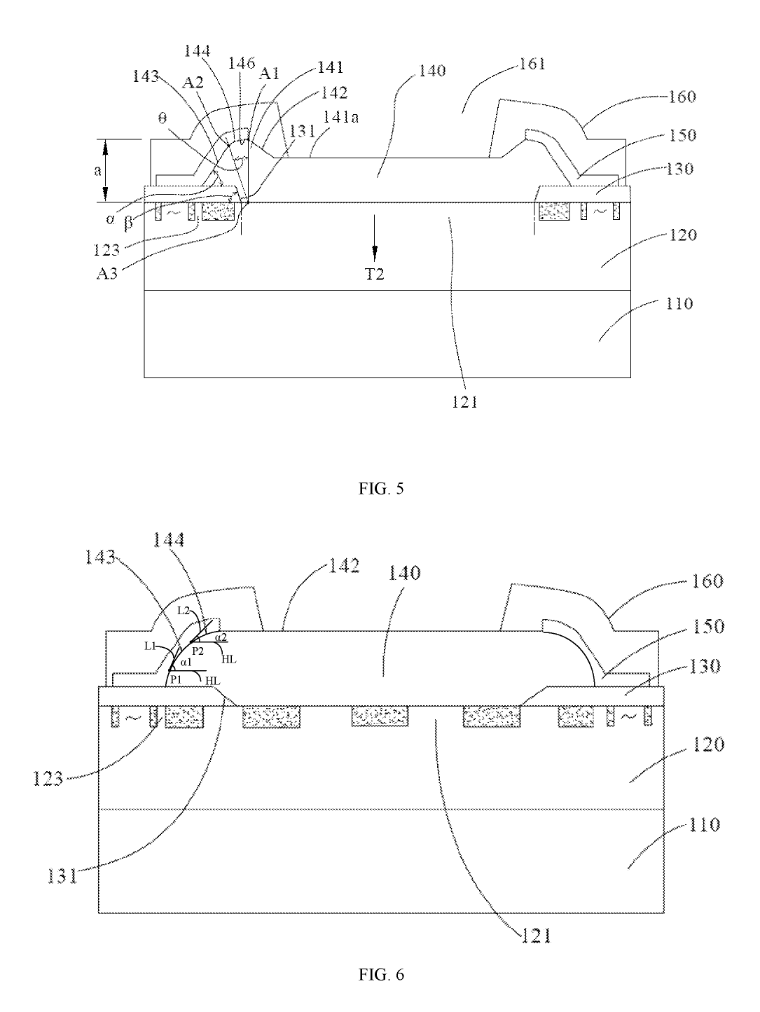

Of course, in some embodiments, the line connecting the first point A1 with the third point A3 does not intersect the field oxide layer 130 at all. That is, the connection surface 144 is projected onto the semiconductor epitaxial layer 120, generating the first projection; the side surface of the field oxide layer 130 is projected onto the semiconductor epitaxial layer 120, generating the second projection; and the first projection completely locates out of the second projection, as shown in FIG. 5.

In some embodiments, an angle between a tangent to the side wall 143 of the anode layer 140 and the surface of the field oxide layer 130 is a second angle α, being in a range of 30°-60°.

In the present embodiment, conditions for photolithography and etching are optimized, for example, the conditions for photolithography and dry etching are optimized, in this way, the angle between the side wall 143 and the surface of the field oxide layer 130 is between 30°-60°. Since the side wall 143 of the anode layer 140 is inclined towards the active region 121, and since the angle between the side wall 143 and the field oxide layer 130 is between 30° and 60°, the passivation layer 150 may transition smoothly from the side wall 143 to the top wall 142 of the anode layer 140. The sharp change in the angle between the side wall 143 and the top wall 142 of the anode layer 140 may be reduced; the stress concentration at the passivation layer above the connection portion, caused by the sharp change, may be reduced; and failure of the power element caused by the moisture entering the power element may be reduced.

Furthermore, since the side wall 143 of the anode layer 140 is inclined towards the active region 121, and since the angle between the side wall 143 and the surface of the field oxide layer 130 is in the range of 30° and 60°, the passivation layer 150 may better grow along the side wall 143 of the anode layer 140, further optimizing the formation of the passivation layer 150 and optimizing the reliability of the power element.

Exemplarily, the angle between the side wall 143 and the field oxide layer 130 may be 45°.

To be noted that, the angle between a tangent to the side wall 143 and the surface of the field oxide layer 130 refers to an acute angle between the tangent to the side wall 143 and the top surface of the field oxide layer 130, i.e., an inclination angle of the side wall 143.

As used herein, the “lower end of the side wall” refers to an end portion of the side wall 143 adjacent to the field oxide layer 130, and the “upper end of the side wall” refers to an end portion of the side wall 143 adjacent to the connection surface 144. In comparison, the “upper corner” and “lower corner” of the anode layer 140, as previously described, refer to the corner between the top wall 142 and the connection surface 144, and the corner between the connection surface 144 and the side wall 143, respectively. The upper end of the side wall 143 is structurally adjacent to the lower corner of the anode layer 140.

To be noted that the semiconductor structure 100 in the present embodiment refers to a silicon carbide diode structure. That is, the present disclosure provides a highly-reliable silicon carbide diode chip structure. By performing a metal etching method after an angle of the photoresist is optimized, the upper corner of the front metal (i.e., the anode layer) is made to be rounded, and the lower corner is controlled between 30° and 60°. In this way, cracks of the passivation layer due to the stress concentration at the corner caused by the steep and straight side wall of the metal anode layer may be reduced, and the moisture resistance of the power element may be improved.

Further, the upper corner of the front metal (i.e., the anode layer) is made to be rounded, and the lower corner is controlled between 30° and 60°. In this way, a climbing angle of the passivation layer may be reduced, the climbing problem of the passivation layer 150 may be solved, and the reliability of the power element may be improved.

In some embodiments, the connection surface 144 includes a first point connected to the top wall 142 and a second point connected to the side wall 143. In the direction extending from the semiconductor epitaxial layer 120 towards the substrate 110, the projection point of the first point projected onto the surface of the field oxide layer 130 is a third point. An angle between the line connecting the third point with the second point and the line connecting the third point with the first point is a first angle θ, which is greater than 5° and less than 45°. Further, an angle between a tangent to the side wall 143 of the anode layer 140 and the surface of the field oxide layer 130 is a second angle α, which is between 30° and 60°.

In this way, since the first angle θ is greater than 5° and less than 45°, and since the second angle α is between 30° and 60°, the stress concentration of the passivation layer 150 at both the upper corner and the lower corner of the side wall 143 of the anode layer 140 is reduced, such that the cracks caused by the stress concentration at the passivation layer 150 at both the upper corner and the lower corner of the side wall 143 of the anode layer 140 may be reduced.

In some embodiments, as shown in FIGS. 1 or 2, each of the substrate 110 and the semiconductor epitaxial layer 120 is silicon carbide. A crystalline type of the substrate 110 is 4H-SiC, a thickness of the substrate 110 is in a range of 250 μm - 350 μm, and a doping concentration of the substrate 110 is in a range of 1E19 - 5E20/cm³. A thickness of the silicon carbide epitaxial layer is in a range of 5 μm - 40 μm, and a concentration is in a range of 5E15 - 5E16/cm³.

To be noted that, the substrate 110 may be a material such as silicon (Si), sapphire (Saphhire), and so on. The substrate 110 is configured for heterogeneous to be epitaxially growing to form the semiconductor epitaxial layer 120. A method for depositing the substrate 110 may include chemical vapor deposition (CVD), vapour phase epitaxy (VPE), metal-organic chemical vapor deposition (MOCVD), low pressure chemical vapor deposition (LPCVD), plasma enhanced chemical vapor deposition (PECVD), pulsed laser deposition (PLD), atomic layer epitaxy, molecular beam epitaxy (MBE), sputtering, evaporation, and so on. Of course, the method for depositing the substrate 110 is limited by the present disclosure.

In addition, the semiconductor epitaxial layer 120 may be epitaxially growing by performing chemical vapor deposition (CVD), vapour phase epitaxy (VPE), metal-organic chemical vapor deposition (MOCVD), low pressure chemical vapor deposition (LPCVD), plasma enhanced chemical vapor deposition (PECVD), pulsed laser deposition (PLD), atomic layer epitaxy, molecular beam epitaxy (MBE). Specific structures and forming methods of the substrate 110 and the semiconductor epitaxial layer 120 may be referred to the semiconductor structures 100 in the art.

In some embodiments, as shown in FIGS. 1 or 2, an angle between the side surface of the field oxide layer 130 and the surface of the terminal region 123 is a third angle β, which is between 30° and 60°. That is, the inclination angle of the side surface of the field oxide layer 130 is between 30° and 60°.

The angle between the side surface of the field oxide layer 130 and the surface of the terminal region 123 refers to the acute angle between the side surface of the field oxide layer 130 and an upper surface of the terminal region 123, i.e., an inclination angle of the side surface of the field oxide layer 130.

In some embodiments, as shown in FIGS. 1 or 2, the anode layer 140 covers the top surface of the field oxide layer 130. Specifically, the anode layer 140 completely covers the first window 131 and partially covers the top surface of the field oxide layer 130.

In some embodiments, as shown in FIGS. 1 or 2, at least partially within the source region 121 is arranged with an injection region (shaded region). The injection region is in contact with the anode layer 140. Specifically, after the semiconductor epitaxial layer 120 is formed, the source region and the terminal region 123 may be formed simultaneously by injecting high energy ions into the semiconductor epitaxial layer 120. The injection region may be a p-doped structure having an injection concentration in a range of 1E17-5E18/cm³. A top view of the injection region within the active region 121 may be, but is not limited to, strip-shaped, square-shaped, hexagon-shaped, or other combinations of structures. The present disclosure does not limit the shape of the injection region.

To be noted that, for the semiconductor device, the anode layer 140 may be in ohmic contact with a P+ region of the active region 121, and the semiconductor device may be a JBS device (junction barrier Schottky diode) or a MPS device (hybrid PIN-Schottky diode), which is in Schottky contact with the N region. In FIG. 1, a surface of the P+ region is connected to a surface of the N region, and the P+ region is an injection region extending from the surface of the N region towards the substrate 110.

In some embodiments, as shown in FIG. 4, the semiconductor device may be an SBD device (Schottky barrier diode), and the metal contact between the anode layer 140 and the active region 121 is the Schottky contact.

Specific structures and principles of the JBS device, the MPS device, and the SBD device may be referred to descriptions in the related art.

To be noted that, the anode layer 140 may be formed by, for example, sputtering or vapour deposition of Schottky metals and front electrode thickening metals. A sputtering temperature is in a range of 400°C-500°C, and a sputtering time length is in a range of 5-10 min. Specific materials of the Schottky metals include, but are not limited to, any one or a combination of metals such as Ti, TiN, TiW, W, Mo, Ta, Ni, and Al. A thickness of the anode layer 140 is in a range of 500A to 3000A. Specific materials of the front electrode thickening metal include, but are not limited to, any one or a combination of metals such as Al, Ag, Cu, and so on. Of course, the anode layer 140 may be formed by other means.

To be noted that the anode layer 140 in the present embodiment may be a multilayer structure, and that is, the anode layer 140 includes the Schottky metal and the front electrode thickening metal. Of course, in other embodiments, the anode layer 140 may alternatively be a single layer of metal, such as a copper layer.

In some embodiments, the anode layer 140 is configured to extend from the active region 121 and is disposed on the top surface of the field oxide layer 130.

In some embodiments, the anode layer 140 located on the top surface of the field oxide layer 130 has an extension length L in a first direction T1. That is, the anode layer 140 is configured to extend from the active region 121 and to be disposed on the top surface of the field oxide layer 130. An extension length L of the anode layer 140 in the first direction is in a range of 0-50 μm. The first direction is a direction from the active region 121 to the terminal region 123. Exemplarily, the anode layer 140 is connected to the field oxide layer 130, and the passivation layer 150 is lapped on both the field oxide layer 130 and the anode layer 140.

It will be understood that the extension length L of the anode layer 140 in the first direction may determine a length of the passivation layer 150 lapping over the top surface of the field oxide layer 130. In this way, the anode layer SUMMARY OF THE DISCLOSURE covers a certain area of the field oxide layer 130, such that a risk of directly exposing the active region 121 may be reduced, and the reliability of the power element is improved. In addition, the anode layer 140 covers a certain area of the field oxide layer 130, such that the edge of the anode layer 140 may be spaced apart from the edge of the field oxide layer 130, and therefore, the passivation layer 150 may lap over the top surface of field oxide layer 130, enabling the passivation layer 150 to cover both the field oxide layer 130 and the side wall 143 of the anode layer 140. In this way, the passivation layer 150, when being deposited, may easily climb along the side wall 143 of the anode layer 140, such that the passivation layer 150 may be formed better.

Exemplarily, in the present embodiment, a length of the part of the passivation layer 150 lapping over the top surface of the field oxide layer 130 is 30 μm.

To be noted that in the above embodiment, the thickness of the field oxide layer 130 is in a range from 6000 A to 12000 A. After the field oxide layer 130 is formed, the first window 131 may be formed by performing a wet etching process, and an etching angle is in a range from 30° to 60°. In this way, the side surface of the field oxide layer 130, from a bottom to a top, is inclined towards the terminal region 123. That is, the first window 131 is an inverted trapezoidal structure, and an inclination angle of the edge of the first window 131 is in a range from 30° to 60°.

In some embodiments, the semiconductor structure 100 further includes a protective layer 160. The protective layer 160 is configured to cover the entire passivation layer 150 and extends to cover a portion of the top wall 142 of the anode layer 140.

Exemplarily, the protective layer 160 defines a second window 161 extending to reach the anode layer 140. The anode layer 140 may further be configured to have a pad region extending from the edge of the protective layer 160 to the active region 121. The protective layer 160 may be polyimide. After forming the anode layer 140 and the passivation layer 150, the polyimide may be spin-coated on the passivation layer 150. Baking and exposing may be performed to define the second window 161. The protective layer 160 may completely cover the entire passivation layer 150 and a part of the anode layer 140, and the passivation layer 150 is encased. Moreover, an edge of the second window 161 may be inclined. In this way, the second window 161 may also be an inverted trapezoidal structure. The protective layer 160 has a thickness in a range of 3.5 μm to 12 μm, such that a better protection may be achieved.

The present embodiment further provides a method of manufacturing a semiconductor structure 100. For manufacturing the semiconductor structure 100, the method includes the following operations.

In an operation S1, a substrate structure is provided.

In some embodiments, the substrate structure includes a substrate 110, a semiconductor epitaxial layer 120 disposed on the substrate 110, an active region 121 and a terminal region 123 disposed in the semiconductor epitaxial layer 120. The active region 121 and the terminal region 123 extend from an inside of the semiconductor epitaxial layer 120 towards a surface facing away from the substrate 110. A field oxide layer 130 is disposed on the semiconductor epitaxial layer 120. The field oxide layer 130 is configured to extend from an edge of the active region 121 towards the terminal region 123.

Exemplarily, the operation S1 may be achieved by performing following operations.

In an operation S11, the substrate 110 is provided.

Exemplarily, as shown in FIG. 11, the substrate 110 may be a silicon carbide substrate 110 for the heterogeneous to be growing epitaxially. A crystalline type of the substrate 110 is 4H-SiC, a thickness of the substrate 110 is in a range of 250 μm - 350 μm, and a doping concentration of the substrate 110 is in a range of 1E19 - 5E20/cm³. A method for depositing the substrate 110 may include chemical vapor deposition (CVD), vapour phase epitaxy (VPE), metal-organic chemical vapor deposition (MOCVD), low pressure chemical vapor deposition (LPCVD), plasma enhanced chemical vapor deposition (PECVD), pulsed laser deposition (PLD), atomic layer epitaxy, molecular beam epitaxy (MBE), sputtering, evaporation, and so on. The substrate 110 may be silicon (Si), sapphire (sapphire), and so on, which will not be limited herein.

In an operation S12, the semiconductor epitaxial layer 120 is formed on the substrate 110.

Exemplarily, as shown in FIG. 12, the semiconductor epitaxial layer 120 may be silicon carbide, and a thickness of the semiconductor epitaxial layer 120 may be in a range of 5 μm - 40 μm, and a concentration is in a range of 5E15 - 5E16/cm³. The semiconductor epitaxial layer 120 may be epitaxially growing on the substrate 110 by performing chemical vapor deposition (CVD), vapour phase epitaxy (VPE), metal-organic chemical vapor deposition (MOCVD), low pressure chemical vapor deposition (LPCVD), plasma enhanced chemical vapor deposition (PECVD), pulsed laser deposition (PLD), atomic layer epitaxy, molecular beam epitaxy (MBE).

To be noted that, epitaxy of the silicon carbide substrate 110 is a basic manufacturing process, the silicon carbide substrate 110 and the silicon carbide epitaxy may be obtained by performing the operations S11 and S12. After the semiconductor epitaxial layer 120 is formed, the active region 121 and the terminal region 123 may be formed by performing injections into the semiconductor epitaxial layer 120. The active region 121 and the terminal region 123 extend from the inside of the semiconductor epitaxial layer 120 towards the surface facing away from the substrate 110. Specifically, the p-doped injection region of the active region 121 and the terminal region 123 may be formed simultaneously by injecting high energy ions. A concentration of the injection is in a range of 1E17 - 5E18/cm³. The injection region within the active region 121 may be, but not limited to, strip-shaped, square-shaped, hexagon-shaped or other combination of structures.

In an operation S13, the field oxide layer 130 is formed on the semiconductor epitaxial layer 120.

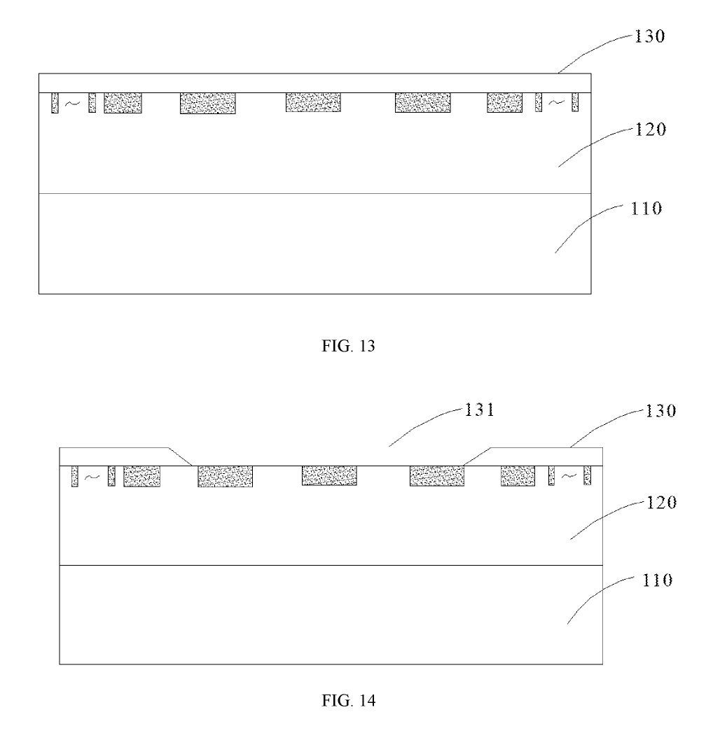

Exemplarily, as shown in FIG. 13, the field oxide layer 130 may be formed on the semiconductor epitaxial layer 120 by performing CVD, and a thickness of the field oxide layer 130 is in a range from 6000 A to 12000 A.

In an operation S14, the field oxide layer 130 may be etched to form a first window 131 exposing the active region 121.

Exemplarily, as shown in FIG. 14, the first window 131 extends to reach the semiconductor epitaxial layer 120 and may be formed by performing a wet etching process. An etching angle is in a range of 30°-60°. In this way, the first window 131 may be an inverted trapezoidal structure, and an inclination angle of an edge of the first window 131 may be in a range of 30° and 60°. While performing the manufacturing in practice, the wet etching process is performed to offset an etching angle of 30°-60° in the terminal region to achieve etching on the field oxide layer 130 on the active region 121. In this way, the first window 131 exposing the active region 121 may be formed by the side surface of the field oxide layer 130 being inclined at the angle of 30°-60° with respect to the surface of the terminal region.

In an operation S2, an anode layer 140 is formed on the field oxide layer 130 and the active region 121.

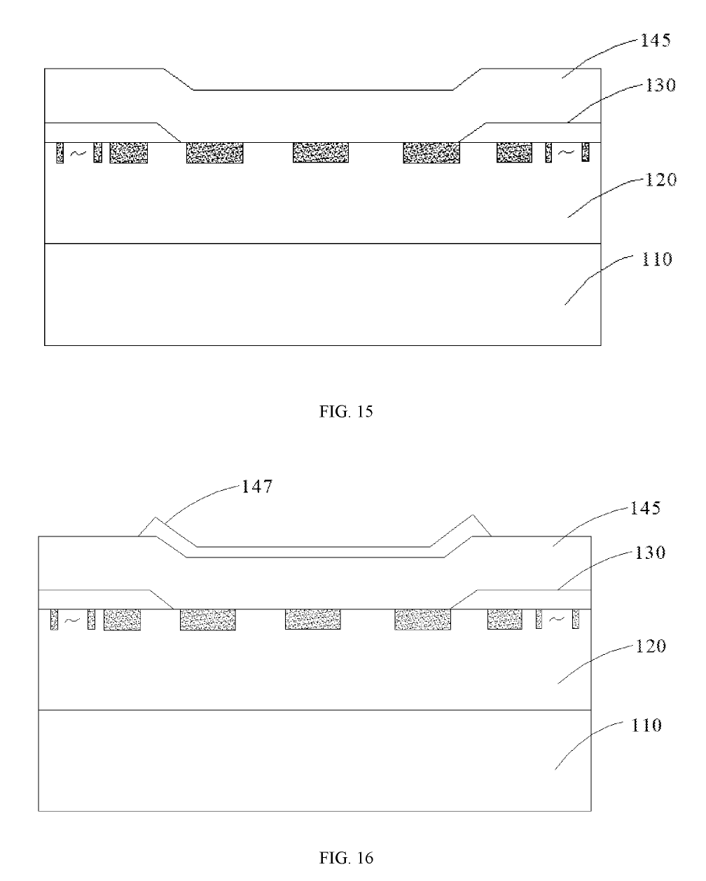

In some embodiments, as shown in FIGS. 15-17, the anode layer 140 is configured to be extending from the active region 121 to cover a portion of the field oxide layer 130. The anode layer 140 includes: a top wall 142 facing away from the active region 121, a side wall 143 facing the field oxide layer 130 and connected to the field oxide layer 130. The side wall 143 of the anode layer 140 is connected to the top wall 142 of the anode layer through a connection surface 144. The connection surface 144 is curved to allow the side wall 143 to be transitioned smoothly to the top wall 142 of the anode layer 140.

In some embodiments, while manufacturing the anode layer 140, the anode layer 140 having a recessed portion may be formed on the active region 121 and the field oxide layer 130. The recessed portion may be arranged on the top wall 142 of the anode layer 140. An edge of the recessed portion may be connected to the side wall of the anode layer 140 through a connection portion. At least a section of the connection portion is the connection surface 144.

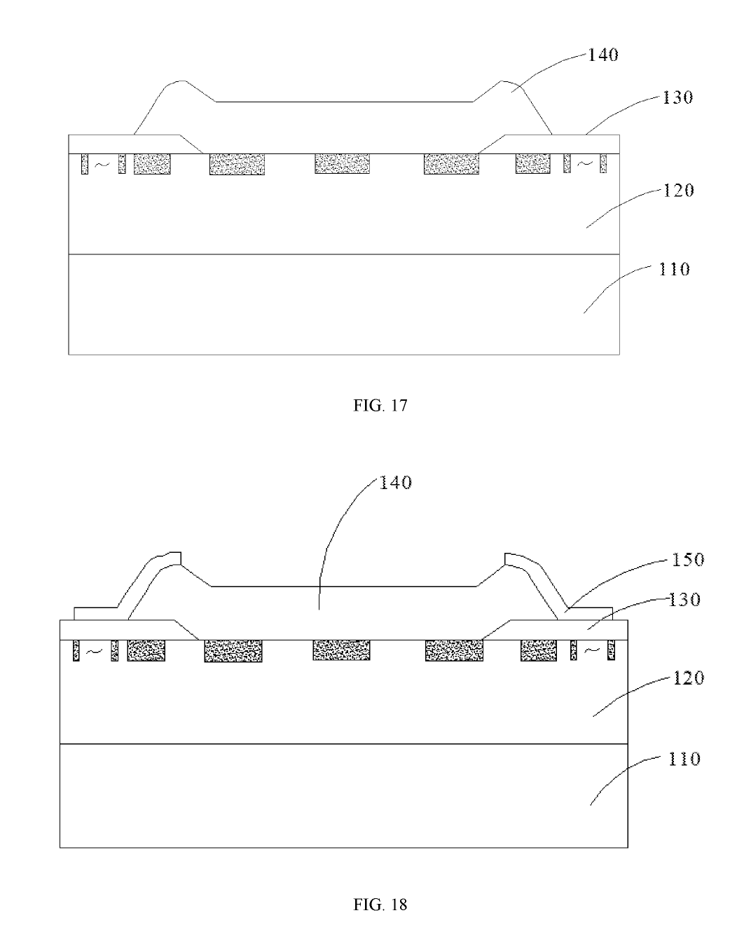

While manufacturing the device in practice, a metal layer 145 may be formed on the field oxide layer 130 and the semiconductor epitaxial layer 120 by sputtering or vapour depositing, as shown in FIG. 15. Further, a photoresist material is coated on the metal layer 145. The photoresist material is inclined towards the active region 121 at a predetermined angle and is then exposed and developed, such that a photoresist layer 147 is formed. The predetermined angle is in a range from 30° to 60°, such that the edge of the photoresist layer 147 is inclined at the angle in the range from 30° to 60°, as shown in FIG. 16. By controlling the exposure and development conditions, the photoresist layer 147 may be formed with a curved profile at its edge, rather than a straight inclined edge. Finally, the photoresist layer 147 serves as a mask, the metal layer 145 is then etched to form the anode layer 140 having a curved connecting surface 144, as in FIG. 17. The photoresist layer 147 is prepared in advance to enable the anode layer 140 to be etched to form a metallic profile having curvature. The upper corner of the side wall 143 of the anode layer 140 is rounded, and the lower corner is inclined at the angle of in the range from 30° to 60°. Further, the edge of the anode layer 140 needs to lap over the field oxide layer 130, and a distance between the edge of the anode layer 140 and the edge of the passivation layer 150 (as shown in FIG. 17) is in a range from 0 to 50 μm. By adjusting the etching parameters (e.g., etching time, gas composition, and plasma power), the metal layer 145 may be etched such that the side wall 143 of the anode layer 140 also has an arcuate profile, with a tangent slope that continuously decreases from a lower end of the side wall 143 adjacent to the field oxide layer 130 toward an upper end of the side wall 143 adjacent to the connection surface 144, as shown in FIG. 6. Such etching conditions may be achieved, for example, by using a dry etching process with a controlled isotropic etching component, which gradually reduces the etching rate from the bottom to the top of the side wall, thereby forming a curved side wall profile.

As a result of the above etching process, the side wall 143 is formed to be curved and outwardly convex toward a direction facing away from the substrate 110. The outwardly convex curvature of the side wall 143 is achieved by the controlled isotropic etching component, which causes the side wall to bulge outward (away from the substrate 110 and away from the active region 121) as the etching progresses from the lower end to the upper end of the side wall. Such outwardly convex configuration provides a smooth and gradually changing slope for the passivation layer 150 to climb along during subsequent deposition, thereby reducing stress concentration and preventing cracks.

Exemplarily, while the metal layer 145 is being etched, such as being dry etched, the etching may be performed along the edge of the photoresist layer 147 to form a side wall of the anode layer having an angle between 30° and 60° with respect to the surface of the field oxide layer 130. By further optimizing the etching conditions, the side wall 143 may be formed with a gradually varying slope, wherein the slope continuously decreases from the lower end of the side wall 143 toward the upper end thereof, thereby forming the arcuate profile as shown in FIG. 6. The optimized etching conditions may include, for example, a gradual reduction of the etching power or a controlled variation of the gas composition during the etching process, such that the upper portion of the side wall is etched less than the lower portion, resulting in a curved side wall with a gradually decreasing slope. Specifically, the etching may be performed along the edge of the photoresist layer 147 to form the anode layer 140 extending from the active region 121 to be disposed on the top surface of the field oxide layer 130, and an extending length of the anode layer 140 is in a range from 0 to 50 μm. The first direction T2 is the direction extending from the active region 121 to the terminal region 123.

In some embodiments, after anode layer 140 is formed after the etching, the photoresist layer 147 may be removed. Further, a protrusion portion 141 is formed on the anode layer 140 corresponding to the edge of the first window 131. The protrusion portion 141 may define the recessed portion. The side wall 143 of the anode layer 140 extends from the protrusion portion 141 to the field oxide layer 130. A connection portion between the surface of the protrusion portion 141 and the side wall 143 of the anode layer 140 is curved.

In an operation S3, a passivation layer 150 is formed on the field oxide layer 130 and the anode layer 140.

Exemplarily, as shown in FIG. 18, the passivation layer 150 is configured to cover the field oxide layer 130 and extends to cover a part of the top wall 142 of the anode layer 140. While manufacturing the device, a high resistance material layer is deposited on the field oxide layer 130 and on the anode layer 140. Further, the high resistance material layer is etched to cover on the side wall of the anode layer 140 and to extend to cover the connection surface 144. The etched high resistance material layer serves as the passivation layer 150.

In practice, the passivation layer 150 is deposited by performing CVD. The passivation layer 150 covers the side wall 143 and extends to cover the protrusion portion 141. The passivation layer 150 may be a double layer medium having silicon oxide and silicon nitride or a silicon nitride medium. A thickness of the passivation layer 150 may be in a range from 8000 A to 15000 A.

To be noted that when depositing the passivation layer 150, a width of the passivation layer 150 covering the connection surface 144 of the anode layer 140 shall not be excessively large. For example, a connection width of the passivation layer 150 covering the connection surface of the anode layer 140 is in a range from 2 μm to 100 μm, preventing the passivation layer 150 from having an excessively large coverage. In this way, cracks, which are caused by excessive shear forces due to inconsistent thermal expansion coefficients, may be prevented from being generated on the passivation layer 150. Of course, in some embodiments where the connection portion 146 includes a connection surface 144 and a transition surface, as shown in FIG. 3, the connection width of the passivation layer 150 covering the connection portion 146 of the anode layer 140 shall not be excessively large, which is in a range from 2μm to 100μm.

In an operation S4, a protective layer 160 is formed on the passivation layer 150.

Exemplarily, as shown in FIG. 1, the protective layer 160 covers the passivation layer 150 and the anode layer 140. The protective layer 160 may be formed by spin-coating polyimide material on the passivation layer 150, exposure baking the polyimide material, and performing shaping. Further, a second window 161 is defined in the protective layer 160, and a thickness of the protective layer 160 is in a range from 3.5 μm to 12 μm.

In summary, the present embodiment provides a semiconductor structure 100. The first window 131 is formed in the field oxide layer 130, and the anode layer 140 is formed to cover the first window 131. In this way, the protrusion portion 141 is formed on the anode layer 140 corresponding to the edge of the first window 131. The side wall 143 of the anode layer 140 extends from the protrusion portion 141 to the field oxide layer 130. The connection portion between the surface of the protrusion portion 141 and the side wall 143 of the anode layer 140 is curved. The passivation layer 150 covers the side wall 143 of the anode layer 140 and extends to cover the protrusion portion 141. By arranging the upper corner of the side wall 143 of the anode layer 140, i.e., the connection portion between the side wall 143 and the protrusion portion 141, to be curved, the side wall 143 may be transitioned smoothly to the protrusion portion 141 of the anode layer 140, preventing a sharp change in the inclination angle, such that the stress concentration of the passivation layer 150 at the corner on the side wall 143 may be prevented. Compared to the related art, for the semiconductor structure 100 of the present embodiment, cracks caused by stress concentration at the corners due to the steep and straight metal layer 145 may be reduced, and the moisture resistance of the power element may be improved.

In addition, by reasonably defining the width of the passivation layer 150, the coverage of the passivation layer 150 may not be excessively broad, such that cracks, which are caused by excessive shear forces due to inconsistent thermal expansion coefficients, may be prevented from being generated on the passivation layer 150.

In addition, since the side wall 143 is transitioned smoothly to the top wall, the passivation layer 150 may be facilitated to extend upwardly when depositing the passivation layer 150, such that climbing of the passivation layer 150 may be achieved better, a better forming quality of the passivation layer 150 may be achieved, and reliability of the power element may be improved. Climbing of the passivation layer 150 may be optimized, the forming quality of the passivation layer 150 may be improved.

To be noted that with respect to the method in the above embodiments, the beneficial effects and benefits of each of these embodiments have been described in detail in the structural embodiments and will not be described in detail here.

The above are only specific embodiments of the present disclosure, but the scope of the present disclosure is not limited to the above embodiments. Any variations or substitutions that can be made of by ordinary skilled person in the art, within the technical scope disclosed by the present invention, shall be covered by the scope of the present invention. Therefore, the scope of the present invention shall be governed by the scope of the claims.

What is claimed is:

1. A semiconductor structure, comprising:
a substrate;
a semiconductor epitaxial layer, disposed on the substrate;
an active region and a terminal region, provided in the semiconductor epitaxial layer;
a field oxide layer, arranged on the semiconductor epitaxial layer and extending from an edge of the active region towards the terminal region;
an anode layer, configured to extend from the active region to be arranged on a portion of the field oxide layer, wherein the anode layer comprises: a top wall, facing away from the active region; a side wall, connected to the field oxide layer; and a connection surface, connected between the side wall of the anode layer and the top wall of the anode layer; the side wall is curved, and an absolute value of a tangent slope of the side wall continuously decreases in a direction from a lower end of the side wall adjacent to the field oxide layer toward an upper end of the side wall adjacent to the connection surface; and
a passivation layer, configured to cover the field oxide layer and extend along the side wall and to cover at least the connection surface.

2. The semiconductor structure according to claim 1, wherein in a cross-sectional view taken perpendicular to a surface of the substrate, the side wall has an arcuate profile, and a radius of curvature of the arcuate profile gradually increases in a direction from the lower end of the side wall toward the upper end of the side wall.

3. The semiconductor structure according to claim 1, wherein an angle between a tangent to the side wall and a surface of the field oxide layer continuously decreases in the direction from the lower end of the side wall toward the upper end of the side wall.

4. The semiconductor structure according to claim 1, wherein the connection surface is curved and outwardly convex toward a direction facing away from the substrate, and an angle between a tangent to the connection surface and a surface of the field oxide layer continuously decreases in the direction from a lower end of the connection surface toward an upper end of the connection surface.

5. The semiconductor structure according to claim 1, wherein a transition between the side wall and the top wall of the anode layer is smooth, and the side wall and the connection surface form an integral arcuate contour.

6. The semiconductor structure according to claim 1, wherein a transition between the side wall and the top wall of the anode layer is smooth, and the side wall, the connection surface, and at least a portion of the top wall jointly form a continuous arcuate contour.

7. The semiconductor structure according to claim 1, wherein the field oxide layer has a side surface that is inclined from a bottom toward a top in a direction toward the terminal region such that a first window defined by the field oxide layer has an inverted trapezoidal structure.

8. The semiconductor structure according to claim 3, wherein the angle between the tangent to the side wall and the surface of the field oxide layer is a second angle α, and the second angle α is a sharp angle.

9. The semiconductor structure according to claim 1, wherein the connection surface comprises a first point connected to the top wall and a second point connected to the side wall; in a direction from the semiconductor epitaxial layer towards the substrate, a projection point of the first point projected onto a surface of the semiconductor epitaxial layer is defined as a third point; and
an angle between a line connecting the third point with the second point and a line connecting the third point with the first point is a first angle θ, and the first angle θ is greater than 5°.

10. The semiconductor structure according to claim 1, wherein the field oxide layer comprises: a top surface, facing away from the terminal region, and a side surface, connected to the top surface and arranged from the top surface towards the active region, wherein the top surface of the field oxide layer is parallel to a surface of the terminal region.

11. The semiconductor structure according to claim 10, wherein the anode layer covers at least a portion of the top surface of the field oxide layer.

12. The semiconductor structure according to claim 10, wherein the anode layer that covers the top surface of the field oxide layer has an extension length in a first direction, the extension length is in a range from 0 to 50 μm, the first direction is defined as a direction extending from the active region to the terminal region.

13. The semiconductor structure according to claim 10, wherein an angle between the side surface of the field oxide layer and a surface of the terminal region is a third angle β, and the third angle β is in a range from 30° to 60°.

14. The semiconductor structure according to claim 1, wherein the top wall of the anode layer has a recessed portion, an edge of the recessed portion is connected to the side wall of the anode layer through a connection portion, and at least a part of the connection portion is the connection surface.

15. The semiconductor structure according to claim 14, wherein the connection portion is the connection surface.

16. The semiconductor structure according to claim 14, wherein the connection portion comprises the connection surface and a part of the top wall; and the passivation layer covers the side wall of the anode layer and extends to cover the connection portion.

17. The semiconductor structure according to claim 14, wherein the connection portion comprises the connection surface and a transition surface, the transition surface is a part of the top wall and is flat, the connection surface is curved, and the passivation layer extends from the side wall to cover the connection surface and the transition surface.

18. The semiconductor structure according to claim 1, further comprising a protective layer, wherein the protective layer is configured to cover the entire passivation layer and extends to cover a portion of the top wall of the anode layer.

19. A semiconductor structure, comprising:
a substrate;
a semiconductor epitaxial layer, disposed on the substrate;
a field oxide layer, arranged on the semiconductor epitaxial layer;
an anode layer, configured to extend from the semiconductor epitaxial layer to be arranged on a portion of the field oxide layer, wherein the anode layer comprises: a top wall, facing away from the semiconductor epitaxial layer; a side wall, connected to the field oxide layer; and a connection surface, connected between the side wall of the anode layer and the top wall of the anode layer; a transition between the side wall and the top wall of the anode layer is smooth; and the side wall is curved and outwardly convex toward a direction facing away from the substrate; and
a passivation layer, configured to cover the field oxide layer and extend along the side wall and to cover at least the connection surface.

20. The semiconductor structure according to claim 19, wherein the connection surface is curved and outwardly convex toward the direction facing away from the substrate.
